(19) United States
(12) Patent Application Publication
(10) Pub. No.: US 2022/0390833 A1
(43) Pub. Date: Dec. 8, 2022

(54) METHOD OF REPLICATING A MICROSTRUCTURE PATTERN

(71) Applicant: VIAVI SOLUTIONS INC., San Jose, CA (US)

(72) Inventor: Riberet ALMEIDA, Rochester, NY (US)

(73) Assignee: VIAVI SOLUTIONS INC., San Jose, CA (US)

(21) Appl. No.: 17/338,118

(22) Filed: Jun. 3, 2021

(51) Int. Cl. G03F 7/00; G03F 7/039; G03F 7/16

(52) U.S. Cl. CPC G03F 7/0002; G03F 7/0392; G03F 7/161

(57) ABSTRACT

A method of replicating a microstructure pattern includes providing a multilayer structure including a substrate, a thin film, and a positive tone photoresist; providing a mold having a microstructure pattern; applying the mold to the multilayer structure under pressure and temperature; wherein the microstructure pattern of the mold is replicated onto the positive tone photoresist of the multilayer structure. An article including a substrate, and a thin film having a microstructure pattern is also disclosed.

### FIELD OF THE INVENTION

The present disclosure generally relates to a method of replicating a microstructure pattern comprising providing a multilayer structure including a substrate, a thin film, and a positive tone photoresist; providing a mold having a microstructure pattern; applying the mold to the multilayer structure under pressure and temperature; wherein the microstructure pattern of the mold is replicated onto the positive tone photoresist of the multilayer structure. An article including the replicated microstructure pattern is also disclosed.

### BACKGROUND OF THE INVENTION

Polymer-on-glass replication processes or stamping processes can be used to create diffuser structures. It is desirable to have a zero-base portion or a base portion with a negligible thickness, e.g., in the order of hundreds of nanometers) of the polymer layer when following with an etching process. For an etch process following a replication of a microstructure, the etch process window needs to be centered around the indentions/protrusions of the microstructures in the polymer layer. It is difficult to control the base portion of the polymer layer after replication, which makes a subsequent etch process of a thin film, such as a high refractive index material, hard to control.

### BRIEF DESCRIPTION OF THE DRAWINGS

Features of the present disclosure are illustrated by way of example and not limited in the following figure(s), in which like numerals indicate like elements, in which:

FIG. 1A illustrates applying a mold having a microstructure pattern to a multilayer structure, according to an aspect of the invention;

FIG. 1B illustrates removal of the mold and replication of the microstructure pattern in a photoresist layer of the multilayer structure;

FIG. 1C illustrates application of a collimated light source, and development of the photoresist layer; and

FIG. 1D illustrates etching of the thin film.

### SUMMARY OF THE INVENTION

In an aspect, there is disclosed a method of replicating a microstructure pattern comprising providing a multilayer structure including a substrate, a thin film, and a positive tone photoresist; providing a mold having a microstructure pattern; applying the mold to the multilayer structure under pressure and temperature; wherein the microstructure pattern of the mold is replicated onto the positive tone photoresist of the multilayer structure.

In another aspect, there is disclosed an article including a substrate, and a thin film having a microstructure pattern.

Additional features and advantages of various embodiments will be set forth, in part, in the description that follows, and will, in part, be apparent from the description, or can be learned by the practice of various embodiments. The objectives and other advantages of various embodiments will be realized and attained by means of the elements and combinations particularly pointed out in the description herein.

### DETAILED DESCRIPTION OF THE INVENTION

For simplicity and illustrative purposes, the present disclosure is described by referring mainly to an example thereof, In the following description, numerous specific details are set forth in order to provide a thorough understanding of the present disclosure, It will be readily apparent however, that the present disclosure may be practiced without limitation to these specific details, In other instances, some methods and structures have not been described in detail so as not to unnecessarily obscure the present disclosure.

Additionally, the elements depicted in the accompanying figures may include additional components and some of the components described in those figures may be removed and/or modified without departing from scopes of the present disclosure. Further, the elements depicted in the figures may not be drawn to scale and thus, the elements may have sizes and/or configurations that differ from those shown in the figures.

It is to be understood that both the foregoing general description and the following detailed description are exemplary and explanatory only, and are intended to provide an explanation of various embodiments of the present teachings. In its broad and varied embodiments, disclosed herein are articles; and a method of making and using articles.

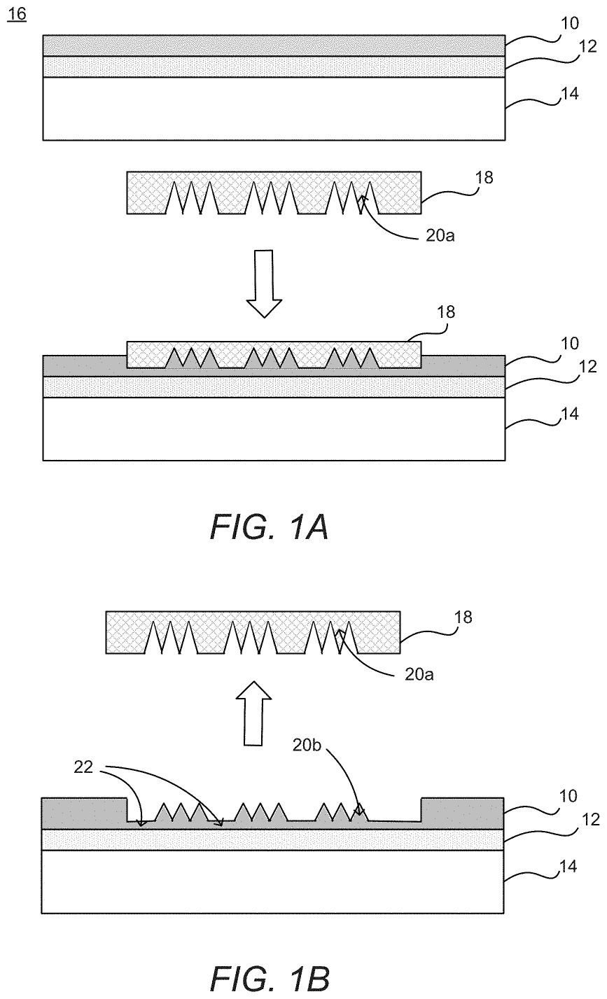

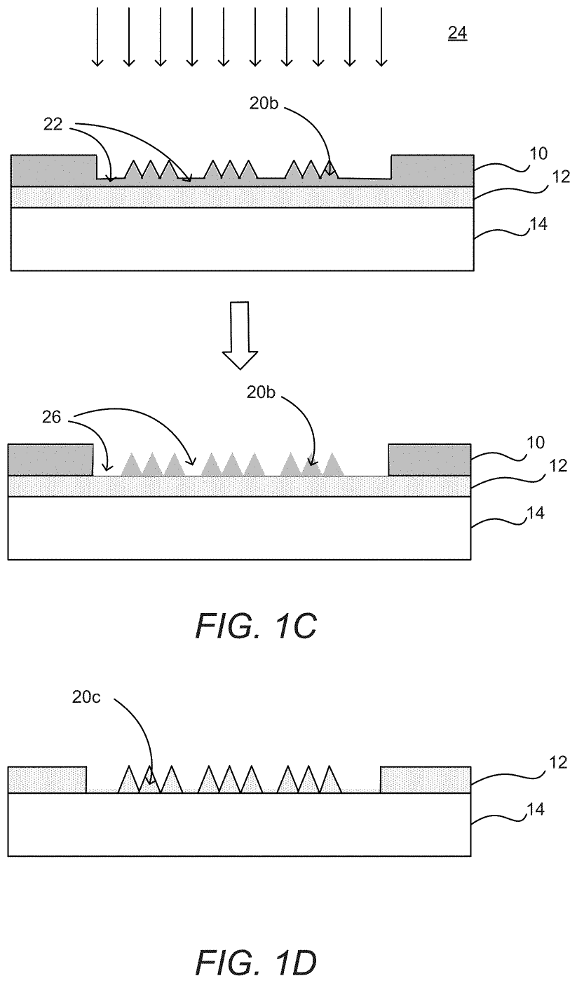

The present disclosure describes a method including providing a multilayer structure 16 including a substrate 14, a thin film 12, and a positive tone photoresist 10; providing a mold 18 having a microstructure pattern 20a; applying the mold 18 to the multilayer structure 16 under pressure and temperature; wherein the microstructure pattern 20a of the mold 18 is replicated 20b onto the positive tone photoresist 10 of the multilayer structure 16, as shown in FIG. 1A.

The multilayer structure 16 can include a substrate 14, a thin film 12, and a positive tone photoresist layer 10. The thin film 12 can be any thin film, including a single layer of material, and/or a multilayer stack. In an aspect, the thin film 12 can be present on a surface of the substrate 14, and on an opposite support, can receive the positive tone photoresist 10. In an aspect, the thin film 12 can be a high refractive index material thin film, i,e., a thin film made of material having a refractive index from about 2 to about 4 at around 940 nm. In an aspect, the thin film 12 can have a gradient or continuous variation in the refractive index or a periodic refractive index profile in the material. The thin film 12 can be present at a thickness ranging from about 1 micron to about 20 microns, for example, from about 1 micron to about 15 microns, and, as a further example, from about 3 microns to about 10 microns. The thin film can be present on a surface of the substrate 14 and/or on a surface of the photoresist 10.

In another aspect, the thin film 12 can be a multilayer stack. The multilayer stack can include one or more layers of a reflector material, a magnetic material, a dielectric material, and an absorbing material.

The substrate 14 can be any material that can receive multiple layers. In an aspect, the thin film 12 can be present on a surface of the substrate, In an aspect, the substrate 14 can be a transparent material. Non-limiting examples of suitable substrate materials include glass and polymers, such as polycarbonate, polymethylmethacrylate, polyethylene terephthalate, polyethylene, amorphous copolyester, polyvinyl chloride; liquid silicon rubber, cyclic olefin copolymers, ionomer resin, transparent polypropylene, fluorinated ethylene propylene, styrene methyl methacrylate, styrene acrylonitrile resin, polystyrene, and methyl methacrylate acrylonitrile butadiene styrene. The substrate 14 can be present at a thickness ranging from about 50 microns to about 2000 microns, for example, from about 100 microns to about 1500 microns, and, as a further example, from about 150 microns to about 1000 microns.

The substrate 14 can be present at a thickness ranging from about 50 microns to about 2000 microns, for example, from about 100 microns to about 1500 microns, and, as a further example, from about 150 microns to about 1000 microns.

In an aspect, the positive tone photoresist 10 can be adjacent (share a common border), and/or can be on a surface of the thin film 12, The positive tone photoresist can be low contrast in photosensitivity similar or dentical to low contrast photoresists used for grayscale lithography. The positive tone photoresist can be a DNQ-Novolac (a mixture of diazonaphthoquinone (DNQ) and novolac resin (phenol formaldehyde resin). Some examples of low contrast photoresists include the AZ® products available from Merck KGaA and MEGAPOSIT™ SPR™ products available from Dow Chemical. The photoresist can be spin coated on the surface of the thin film 12 to a thickness of few microns to tens of microns. In an aspect, the photoresist 10 can be spray coated on the surface of the thin film 12. A thickness of the photoresist 10 can be greater than a peak to valley height of the structures on the mold 18 for effective embossing/stamping with good fidelity.

As shown in FIG. 1A, a mold 18 can have a microstructure pattern 20a. The mold 18 can be made of a material capable of receiving and retaining a microstructure pattern 20a. Non-limiting examplesof a material include metal; a semiconductor; a dielectric, such as nickel, silicon, fused silica, etc.; glass; quartz; and combinations thereof. In an aspect, the mold 18 can be made of a conductive material. In another aspect, the mold 18 can be made of a thermally conductive material, and having the microstructure pattern 20a.

The microstructure pattern 20a can be a random or a periodic pattern. In an aspect, the microstructure pattern 20a can be a binary pattern. In another aspect, the microstructure pattern 20a can be a gray-scale non-binary pattern. The microstructure pattern 20a can include a variety of shapes, forms, images, indentations, protrusions, and combinations thereof, in a variety of sizes. The microstructure pattern 20a can include uniform portions and irregular portions, For example, as shown in FIG. 1A, the microstructure pattern 20a includes three separate portions of triangular-shaped indentations that are uniformly separated one from another by planar sections.

In an aspect, the mold 18 can include a release agent (not shown), applied as a coating, on the microstructure pattern 20a, The release agent can be a low surface energy fluoropolymer or a hydrophobic self-assembled-monolayer, such as a hydrophobic silane, The release agent can be applied to the mold 18 in any deposition process that can deposit the release agent in the indentations/protrusions, etc. of the microstructure pattern 20a. Non-limiting examples of a suitable deposition process include spin coating and dip coating; chemical vapor deposition; physical vapor deposition, such as sputter or thermal evaporation; and a physical application, such as buffing a surface of the microstructure pattern 20a with the release agent.

As shown in FIG. 1A, the mold 18 can be applied to a surface of the photoresist 10 of the multilayer structure 16, The method can include applying pressure and temperature to the mold 18 and/or the multilayer structure 16. In an aspect, the step of applying the mold 18 to the multilayer structure 16 can be an embossing process or a stamping process. The heated mold 18 can be brought in contact to the photoresist surface and can be positioned there for anywhere from about 1 to about 10 seconds before a pressure can be applied. The embossing time, once pressure is applied to the mold 18. can range from about 1 second to about 30 seconds. Temperatures can range from about 60° C. to about 90° C. Pressure can range from about 5 PSI to about 60 PSI. In an aspect, the process conditions included a temperature of about 167° F. (75° C.) for about 20 seconds, at a pressure of about 10 PSI. In another aspect, the process conditions included a temperature of about 167° F. (75° C.) for about 20 seconds at a pressure of about 20 PSI.

In this manner, the microstructure pattern 20a of the mold 18 can be replicated and/or substantially replicated onto the positive tone photoresist 10 of the multilayer structure 16. In an aspect, the replicated microstructure pattern 20b can be opposite in phase and/or polarity from the original microstructure pattern 20a.

The method includes removing the mold 18 from the multilayer structure 16, as shown in FIG. 1B, The positive tone photoresist 10 can have a replicated microstructure pattern 20b and can also include a base portion 22 of the positive tone photoresist 10 that does not have the replicated microstructure pattern 20b, The base portion 22 of the positive tone photoresist 10 can have an initial thickness ranging from about 0.001 μm to about 10 microns, for example, from about 0.01 microns to about 8 microns, and as a further example from about 0.1 microns to about 5 microns.

The replicated microstructure pattern 20b can be an inverse of the microstructure pattern 20a of the mold 18. For example, whereas the microstructure pattern 20a of the mold 18 can include includes three eparate portions of triangular-shaped indentations; the microstructure pattern 20b of the photoresist 10 can include three separate portions of triangular-shaped protrusions.

As shown in FIG. 1C, the method can include applying a flood exposure using a collimated light source 24 to the multilayer structure 16, wherein the collimated light 24 exposes the replicated microstructure pattern 20b and the base portion 22 of the photoresist 10 that does not have the replicated microstructure pattern 20b. The collimated light source 24 can be a light source that emits collimated light, such as a photomask aligner lamp or a dedicated i-line UV exposure tool or a UV-LED/laser setup. In another aspect, the collimated light source can be a source that emits collimated light, such as a lens or mirror that receives diffused light and emits collimated light.

The application of a flood exposure can be followed by a subsequent development step. In particular, the method can include developing the base portion 22 of the positive tone photoresist 10 at a uniform rate of speed. The development of the base portion 22 can be to completion, e.g., so that no base portion 22 is present between the microstructure pattern 20b and a surface of the thin film 12, as shown in FIG. 1C, so that a surface portion 26 of the underlying thin film 12 can be completely exposed. In an aspect, the development of the base portion 22 can be near completion or reside a few hundreds of nanometers to a few microns directly below the replicated microstructure pattern 20b and above the thin film 12 (not shown).

The development step can include application of an aqueous-alkaline based developer to the photoresist 10. In an aspect, after application of the collimated light, a structure includes a substrate 14, a thin film 12, and the replicated microstructure pattern 20b, which is adjacent to or on surface of the thin film 12. In an aspect, the base portion 22 of the photoresist 10 is not present after development following exposure to the collimated light. In another aspect, the base portion 22, after exposure to the collimated light and the development, can have a reduced thickness as compared to an initial thickness of the base portion 22, after application of the mold 18.

As shown in FIG. 1D, the method also includes etching the photoresist 10 and the thin film 12 to form an etched microstructure pattern 20c into the thin film 12. After etching, the thin film 12 includes a portion with the replicated microstructure pattern 20c; and/or a portion with an original thickness of the thin film 12. There can be a portion that does not include any thin film 12, i.e., there is an absence of the thin film 12. The step of etching can be performed using any technique that will etch the photoresist material. Non-limiting examples of suitable etching techniques include reactive ion etching (RIE), Inductively coupled plasma—reactive ion etching (ICP-RIE), and ion milling. The etching can remove any remaining photoresist 10 from the multilayer structure 16, such as from surface of the thin film 12. The etching can transfer the morphology of the microstructure pattern 20b in the photoresist into the thin film 12.

The etched microstructure pattern 20c in the thin film 12 can have an opposite polarity, and can or cannot have a same aspect ratio as the microstructure pattern 20a of the mold 18, The etched microstructure pattern 20c in the thin film 12 can have the same polarity, and can or cannot have a same aspect ratio as the replicated microstructure pattern 20b in the photoresist 10.

From the foregoing description, those skilled in the art can appreciate that the present teachings can be implemented in a variety of forms. Therefore, while these teachings have been described in connection with particular embodiments and examples thereof, the true scope of the present teachings should not be so limited. Various changes and modifications can be made without departing from the scope of the teachings herein.

This scope disclosure is to be broadly construed. It is intended that this disclosure disclose equivalents, means, systems and methods to achieve the coatings, devices, activities and mechanical actions disclosed herein. For each coating, device, article, method, mean, mechanical element or mechanism disclosed, it is intended that this disclosure also encompass in its disclosure and teaches equivalents, means, systems and methods for practicing the many aspects, mechanisms and devices disclosed herein. This disclosure is intended to encompass the equivalents, means, systems and methods of the use of the article, such as an optical device of manufacture and its many aspects consistent with the description and spirit of the operations and functions disclosed herein. The claims of this application are likewise to be broadly construed. The description of the inventions herein in their many embodiments is merely exemplary in nature and, thus, variations that do not depart from the gist of the invention are intended to be within the scope of the invention. Such variations are not to be regarded as a departure from the spirit and scope of the invention.

What is claimed is:

1. A method, comprising:
providing a multilayer structure including a substrate, a thin film, and a positive tone photoresist;
providing a mold having a microstructure pattern;
applying the mold to the multilayer structure under pressure and temperature;
wherein the microstructure pattern of the mold is replicated onto the positive tone photoresist of the multilayer structure.

2. The method of claim 1, wherein the positive tone photoresist is a mixture of diazonaphthoquinone and novolac resin.

3. The method of claim 1, wherein the thin film is high refractive index thin film.

4. The method of claim 1, wherein the mold having the microstructure pattern is coated with a release agent.

5. The method of claim 1, wherein the mold having the microstructure pattern is made of a material chosen from a metal, a semiconductor, a dielectric material, and combinations thereof.

6. The method of claim 1, wherein the microstructure pattern of the mold is a grayscale pattern.

7. The method of claim , wherein the microstructure pattern of the mold is a random pattern.

8. The method of claim 1, wherein the step of applying the mold to the Multilayer structure is an mbossing process.

9. The method of claim 1, further comprising, removing the mold from the multilayer structure.

10. The method of claim 1, wherein the positive tone photoresist having the replicated microstructure pattern includes a base portion of the positive tone photoresist that does not have the replicated microstructure pattern.

11. The method of claim 10, wherein the base portion of the positive photoresist has a thickness ranging from about 0.001 um to about 10 microns.

12. The method of claim 9, further comprising, applying a flood exposure using a collimated light source to the positive tone photoresist;
wherein the collimated light exposes the replicated microstructure pattern and the base portion of the positive tone photoresist.

13. The method of claim 12, further comprising developing the base portion of the positive photoresist at a uniform rate of speed.

14. The method of claim 13, wherein the development step reduces a thickness of the base portion of the positive photoresist so that a surface portion of the thin film is exposed.

15. The method of claim 13 further comprising, etching the thin film to form an etched microstructure pattern.

16. The method of claim 15, wherein the step of etching the thin film is a process chosen from reactive ion etching, Inductively Coupled Plasma—Reactive Ion Etching process, and an Ion milling process.

17. The method of claim 13, wherein the step of etching removes any remaining positive tone photoresist from the multilayer structure.

18. The method of claim 15, wherein the etched microstructure pattern in the thin film is opposite in phase/polarity to the microstructure pattern of the mold.

19. The method of claim 1, wherein the replicated microstructure pattern in the positive tone photoresist is the same as the microstructure pattern of the mold and is opposite in phase/polarity.

20. The method of claim 15, wherein the etched microstructure pattern in the thin film is the same in terms of phase/polarity as the replicated microstructure pattern in the positive tone photoresist anddoes not have the same aspect ratio.
